(19) United States
(12) Patent Application Publication
(10) Pub. No.: US 2024/0389397 A1
(43) Pub. Date: Nov. 21, 2024

(54) LIGHT EMITTING DISPLAY APPARATUS

(71) Applicant: SAMSUNG ELECTRONICS CO., LTD., SUWON-SI (KR)

(72) Inventors: JISOO HAM, SUWON-SI (KR); KYUNGLYONG KANG, SUWON-SI (KR); JUNGU KANG, SUWON-SI (KR); YOUNGMOK KIM, SUWON-SI (KR); SEONGJIN PARK, SUWON-SI (KR); YEONKWANG LEE, SUWON-SI (KR); YONGSANG JEONG, SUWON-SI (KR)

(21) Appl. No.: 18/609,327

(22) Filed: Mar. 19, 2024

(30) Foreign Application Priority Data
Mar. 24, 2023 (KR) 10-2023-0039258
May 16, 2023 (KR) 10-2023-0063363

(51) Int. Cl. H10K 59/122; H10K 59/35; H10K 59/80

(52) U.S. Cl. CPC H10K 59/122; H10K 59/35; H10K 59/805

(57) ABSTRACT

A light emitting display apparatus includes an insulating layer arranged on a substrate. The insulating layer includes a trench. A first electrode is arranged on the insulating layer. A light emitting layer is arranged on the insulating layer and the first electrode. A separator is arranged between the insulating layer and the light emitting layer. The separator covers at least one sidewall of the trench. A second electrode is arranged on the light emitting layer. The separator includes a recess portion having at least a portion concavely defined in a horizontal direction on the substrate.

### CROSS-REFERENCE TO RELATED APPLICATION

This application claims priority under 35 U.S.C. § 119 to Korean Patent Application No. 10-2023-0039258, filed on Mar. 24, 2023 in the Korean Intellectual Property Office (KIPO), and Korean Patent Application No. 10-2023-0063363, filed on May 16, 2023 in KIPO, the disclosures of which are incorporated by reference in their entireties herein.

### 1. TECHNICAL FIELD

The present inventive concept relates to a light emitting display apparatus.

### 2. DISCUSSION OF RELATED ART

The demand for display apparatuses for displaying images in various forms has increased along with the development of the information society. Accordingly, in recent years, various display apparatuses such as Liquid Crystal Displays (LCDs), Plasma Display Panel (PDPs), and Organic Light Emitting Display (OLEDs) have been developed.

Among the display apparatuses, an OLED is a self-luminous type which provides an increased viewing angle and contrast ratio as compared to LCD, and does not require a separate backlight. Thus OLEDs are relatively lightweight and thin and have relatively low power consumption. In addition, OLEDs provide a DC low voltage drive, fast response, and reduced manufacturing costs.

### SUMMARY

Embodiments of the present inventive concept provides a light emitting display apparatus including a separator having a recess portion formed thereon.

According to an embodiment of the present inventive concept, a light emitting display apparatus includes an insulating layer arranged on a substrate. The insulating layer includes a trench. A first electrode is arranged on the insulating layer. A light emitting layer is arranged on the insulating layer and the first electrode. A separator is arranged between the insulating layer and the light emitting layer. The separator covers at least one sidewall of the trench. A second electrode is arranged on the light emitting layer. The separator includes a recess portion having at least a portion concavely defined in a horizontal direction on the substrate.

According to an embodiment of the present inventive concept, a light emitting display apparatus includes an insulating layer arranged on a substrate. The insulating layer includes a trench. A first electrode is arranged on the insulating layer. A light emitting layer is arranged on the insulating layer and the first electrode. A separator is arranged between the insulating layer and the light emitting layer. The separator covers at least one sidewall of the trench. A second electrode is arranged on the light emitting layer. The separator includes a recess portion having at least a portion that is concavely defined in a horizontal direction on the substrate. The light emitting layer includes a charge generation layer that is disconnected inside the trench, including in a region overlapping the recess portion.

According to an embodiment of the present inventive concept, a light emitting display apparatus includes a substrate having a plurality of pixels. The plurality of pixels including first to third pixels. An insulating layer is arranged on the substrate. The insulating layer includes a trench. A first electrode is arranged on the insulating layer. A light emitting layer is arranged on the insulating layer and the first electrode. A separator is arranged between the insulating layer and the light emitting layer. The separator covers at least one sidewall of the trench. A second electrode is arranged on the light emitting layer. An encapsulation layer is arranged on the second electrode. The separator includes at least one first separator and at least one second separator that are formed alternately stacked on one another. The second separator includes a recess portion having at least a portion concavely defined in a horizontal direction on the substrate. The light emitting layer includes a charge generation layer that is disconnected inside the trench, including in a region overlapping the recess portion.

### BRIEF DESCRIPTION OF THE DRAWINGS

Embodiments of the present inventive concept will be more clearly understood from the following detailed description taken in conjunction with the accompanying drawings in which:

FIG. 1 is a plan view showing a schematic configuration of a light emitting display apparatus according to an embodiment of the present inventive concept;

FIG. 2 is a cross-sectional view of a light emitting display apparatus taken along line AA′ of FIG. 1 according to an embodiment of the present inventive concept;

FIG. 3 is an enlarged cross-sectional view of a portion CX1 of FIG. 2 according to an embodiment of the present inventive concept;

FIGS. 4 to 7 are cross-sectional views sequentially illustrating a process of manufacturing the light emitting display apparatus of FIG. 2 according to embodiments of the present inventive concept;

FIG. 8 is a cross-sectional view of a light emitting display apparatus taken along line AA′ of FIG. 1 according to an embodiment of the present inventive concept;

FIG. 9 is an enlarged cross-sectional view of a portion CX2 of FIG. 8 according to an embodiment of the present inventive concept;

FIG. 10 is a cross-sectional view of a light emitting display apparatus taken along line AA′ of FIG. 1 according to an embodiment of the present inventive concept;

FIG. 11 is an enlarged cross-sectional view of a portion CX3 of FIG. 10 according to an embodiment of the present inventive concept; and

FIGS. 12 to 15 are cross-sectional views sequentially illustrating a process of manufacturing the light emitting display apparatus of FIG. 10 according to embodiments of the present inventive concept.

### DETAILED DESCRIPTION OF EMBODIMENTS

Hereinafter, embodiments of the present inventive concept will be described in detail with reference to the accompanying drawings. The same reference numerals are used for the same components in the drawings, and redundant descriptions thereof are omitted.

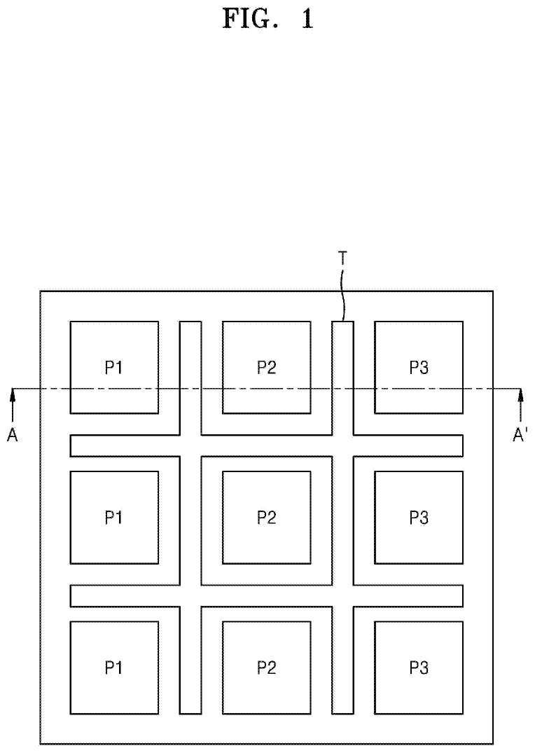

FIG. 1 is a plan view showing a schematic configuration of a light emitting display apparatus according to an embodiment.

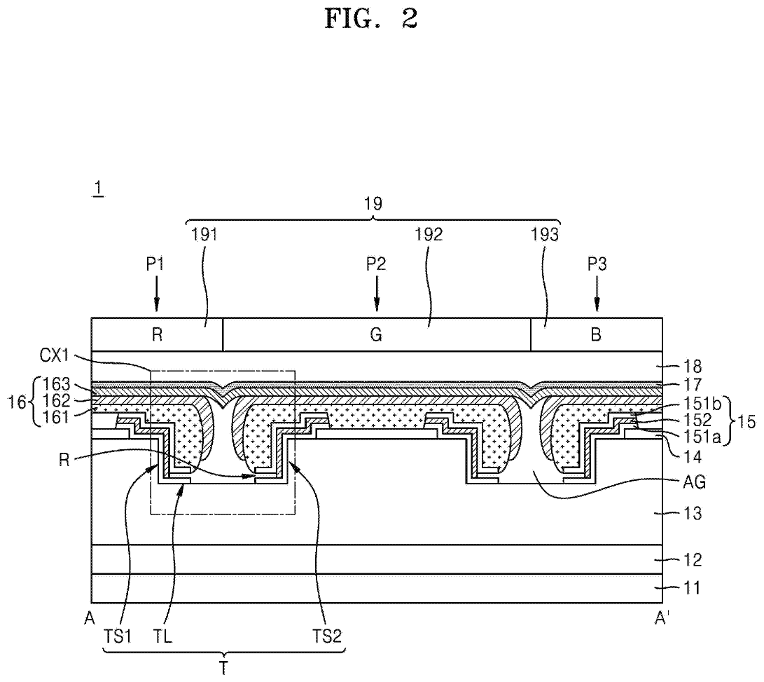

Referring to FIGS. 1 and 2, a light emitting display apparatus 1 according to an embodiment may include all or a portion of a substrate 11, first to third pixels P1 to P3, and a trench T.

The first to third pixels P1 to P3 may be provided above the substrate 11. In an embodiment, the first to third pixels P1 to P3 may be sequentially arranged in a first direction (horizontal direction of FIG. 1). However, embodiments of the present inventive concept are not necessarily limited thereto. In addition, in an embodiment a plurality of first pixels P1 that emit light of the same color may be arranged in a second direction (longitudinal direction of FIG. 1). A plurality of second pixels P2 that emit light of the same color may be arranged in a second direction (longitudinal direction of FIG. 1). A plurality of third pixels P3 that emit light of the same color may be arranged in a second direction (longitudinal direction of FIG. 1). However, embodiments of the present inventive concept are not necessarily limited thereto.

In an embodiment, the first pixels P1 may emit light of a first color, for example, red light. The second pixels P2 may emit light of a second color, for example, green light. The third pixels P3 may emit light of a third color, for example, blue light. However, the arrangement structures of the plurality of first to third pixels P1 to P3 and the colors emitted by the pixels are not necessarily limited thereto and may be variously changed.

The trenches T may be formed in boundary regions between adjacent pixels of the first to third pixels P1 to P3. For example, in an embodiment one trench T may be formed in a boundary region between the first pixel P1 and the second pixel P2, and another trench T may be formed in a boundary region between the second pixel P2 and the third pixel P3.

The trench T may extend in a second direction (longitudinal direction of FIG. 1) along the boundary region between the first pixel P1 and the second pixel P2 above the substrate 11. In addition, the trench T may extend in the second direction (longitudinal direction of FIG. 1) along the boundary region between the second pixel P2 and the third pixel P3 above the substrate 11.

In addition, trenches T may be respectively formed in boundary regions between a plurality of first pixels P1, boundary regions between a plurality of second pixels P2, and boundary regions between a plurality of third pixels P3, which emit light of the respectively same colors.

These trenches T may respectively extend in the first direction (horizontal direction of FIG. 1) along the boundary regions between a plurality of first pixels P1, the boundary regions between a plurality of second pixels P2, and the boundary regions between a plurality of third pixels P3 above the substrate 11.

In an embodiment, the trenches T each may be formed in a lattice shape. However, the formation position and structure of the trenches T are not necessarily limited thereto, and may be variously changed.

Hereinafter, the light emitting display device 1 according to an embodiment will be described with reference to cross-sectional views.

FIG. 2 is a cross-sectional view schematically illustrating a cross-section taken along line AA′ of the light emitting display apparatus of FIG. 1 according to an embodiment.

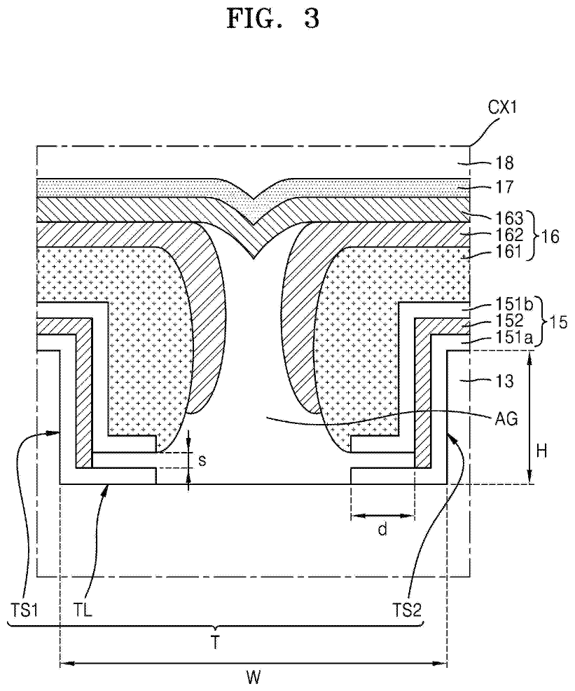

FIG. 3 is an enlarged cross-sectional view of a portion CX1 of FIG. 2.

Referring to embodiments of FIGS. 2 and 3, the light emitting display apparatus 1 according to an embodiment may include all or a portion of the substrate 11, a circuit element layer 12, an insulating layer 13, a first electrode 14, a separator 15, a light emitting layer 16, a second electrode 17, an encapsulation layer 18, and a color filter 19.

In an embodiment, the substrate 11 may be made of a semiconductor material such as a silicon wafer. However, embodiments of the present inventive concept are not necessarily limited thereto. For example, in some embodiments the substrate 11 may be made of a material such as glass or plastic. The first to third pixels P1 to P3 may be provided above the substrate 11.

The circuit element layer 12 may be formed on the substrate 11 (e.g., formed directly thereon). Circuit elements including various signal lines, thin layer transistors, capacitors, and the like may be provided in the circuit element layer 12 for each of the pixels P1 to P3. In an embodiment, the signal lines may include gate lines, data lines, power lines, and reference lines. In an embodiment, the thin layer transistors may include a switching thin layer transistor, a driving thin layer transistor, and a sensing thin layer transistor.

The switching thin layer transistor may be switched according to a gate signal supplied to a gate line to supply a data voltage supplied from the data line to the driving thin layer transistor. The driving thin layer transistor may be switched according to the data voltage supplied from the switching thin layer transistor to generate a data current from a power supply from the power line and supply the data current to the first electrode 14. The sensing thin layer transistor senses a threshold voltage deviation of the driving thin layer transistor that causes image quality degradation, and may supply the current of the driving thin layer transistor to the reference line in response to a sensing control signal supplied from a gate line or a separate sensing line.

The capacitors maintain the data voltage supplied to the driving thin layer transistor for one frame, and may be connected to the gate terminal and the source terminal of the driving thin layer transistor, respectively.

The insulating layer 13 may be formed on the circuit element layer 12 (e.g., formed directly thereon). In an embodiment, the insulating layer 13 may be formed of an organic layer such as acrylic resin, epoxy resin, phenolic resin, polyamide resin, and polyimide resin. Alternatively, the insulating layer 13 may be formed of an inorganic layer such as silicon nitride, aluminum nitride, zirconium nitride, titanium nitride, hafnium nitride, tantalum nitride, silicon oxide, aluminum oxide, or titanium oxide. However, embodiments of the present inventive concept are not necessarily limited thereto.

The trenches T may be respectively formed in the boundary region between the first pixel P1 and the second pixel P2 and the boundary region between the second pixel P2 and the third pixel P3, in the insulating layer 13. In an embodiment, the trenches T may be formed between the first electrodes 14, and may extend to a predetermined region inside the insulating layer 13 without penetrating the insulating layer 13. However, embodiments of the present inventive concept are not necessarily limited thereto, and in some embodiments the trench T may penetrate the insulating layer 13 and extend to a predetermined region inside the circuit element layer 12 below the insulating layer 13.

The separators 15 may be formed in boundary regions between adjacent two pixels of the first to third pixels P1 to P3. In an embodiment, the separators 15 may be formed in a matrix structure. For example, each of the separators 15 may be formed of first separators 151a and 151b and second separator 152, which are alternately stacked. In an embodiment, the first separators 151a and 151b may include silicon nitride, and the second separator 152 may include silicon oxide. However, embodiments of the present inventive concept are not necessarily limited thereto, and the first separators 151a and 151b and the second separator 152 may include materials having different etching selectivity from each other.

The separators 15 may be arranged between the insulating layer 13 and the light emitting layer 16. The separators 15 may be formed to cover the sidewalls, such as first and second sidewalls TS1 and TS2, of the trenches T. In addition, the separators 15 may cover at least a portion of the bottom surfaces TL of the trenches T. In addition, the separators 15 may be formed to cover both ends of the first electrode 14 provided in each of the first to third pixels P1 to P3. Accordingly, the exposed region of the first electrode 14 that is not covered by the separators 15 may be a light emitting region.

Each of the separators 15 may include one or more recess portions R. In an embodiment, each of the recess portions R may be concavely formed by being inserted into a portion of the separator 15 in a horizontal direction parallel to the substrate 11. For example, in an embodiment each of the recess portions R may be concavely formed by being inserted into a portion of the second separator 152 in a horizontal direction parallel to the substrate 11.

The recess portions R may be formed on the first sidewall TS1 and the second sidewall TS2 of each of the trench T, respectively. The recess portions R are formed in a pair on the first sidewall TS1 and the second sidewall TS2 of each trench T, and vertical levels of the pair of recess portions R may be the same as each other. Depths d and heights s of the pair of recess portions R may be the same as each other. In an embodiment, the depth d of the recess portion R may be about 63 nm, and the height s of the recess portion R may be about 53 nm.

However, embodiments of the present inventive concept are not necessarily limited thereto, and the number and shape of the recess portions R may be variously arranged. For example, in some embodiments the recess portions R may be formed only on the first sidewall TS1 or the second sidewall TS2 of each of the trenches T. In addition, the vertical levels of the pair of recess portions R may be formed differently from each other, and the depths d and/or heights s of the pair of recess portions R may be formed differently from each other.

The light emitting layer 16 may be formed on the insulating layer 13. For example, the light emitting layer 16 may be formed on the insulating layer 13, the separator 15, and the first electrode 14. The light emitting layer 16 may be formed in a stacked structure including one or more layers.

In an embodiment, the light emitting layer 16 may be provided to emit light, such as white light. For example, the light emitting layer 16 may include a plurality of stacks emitting light of different colors. For example, the light emitting layer 16 may include a first stack 161, a second stack 163, and a charge generation layer (CGL) 162 provided between the first stack 161 and the second stack 163. The charge generation layer 162 may be stacked on the first stack 161, and the second stack 163 may be stacked on the charge generation layer 162. However, embodiments of the present inventive concept are not necessarily limited thereto, and the light emitting layer 16 may be formed in a structure in which a plurality of stacks and a plurality of charge generation layers are alternately stacked.

In an embodiment, the first stack 161 may include a first hole transport layer, a first organic light emitting layer, and a first electron transport layer, which are sequentially stacked. The second stack 163 may include a second hole transport layer, a second organic light emitting layer, a second electron transport layer, and an electron injection layer, which are sequentially stacked. The charge generation layer 162 may include an n-type charge generation layer that supplies electrons to the first stack 161 and a p-type charge generation layer that supplies holes to the second stack 163. For example, the n-type charge generation layer may inject electrons into the first stack 161, and the p-type charge generation layer may inject holes into the second stack 163. In an embodiment, the n-type charge generation layer may be composed of an organic layer doped with an alkali metal such as Li, Na, K, or Cs, or an alkaline earth metal such as Mg, Sr, Ba, or Ra. The p-type charge generation layer may be formed by doping an organic material having hole transport capability with a dopant.

The light emitting layer 16 may be formed inside and above the trench T. In an embodiment in which the light emitting layer 16 is formed inside the trench T, at least a portion of the light emitting layer 16 is disconnected, so that leakage current may be prevented from occurring between adjacent two pixels P1 to P3.

For example, the first stack 161 may be formed on each of the sidewalls TS1 and TS2 of each trench T. In an embodiment, the first stack 161 may also be formed on the bottom surface TL of each trench T. However, the first stack 161 may be disconnected inside the trench T, including in a region overlapping the recess portion R.

For example, the first stack 161 formed on the first sidewall TS1 of the trench T and the first stack 161 formed on the second sidewall TS2 of the trench T may not be connected with each other. Accordingly, charges may not move through the first stack 161 between the first pixel P1 and the second pixel P2 and between the second pixel P2 and the third pixel P3, which are arranged adjacent to each other with the trench T therebetween.

The charge generation layer 162 may be formed on the first stack 161. In an embodiment, the charge generation layer 162 may also be formed on the bottom surface TL of each trench T. However, the charge generation layer 162 may be disconnected inside the trench T, including in a region overlapping the recess portion R.

For example, the charge generation layer 162 formed on the first sidewall TS1 of the trench T and the charge generation layer 162 formed on the second sidewall TS2 of the trench T may not be connected with each other. Accordingly, charges may not move through the charge generation layer 162 between the first pixel P1 and the second pixel P2 and between the second pixel P2 and the third pixel P3, which are arranged adjacent to each other with the trench T therebetween.

In an embodiment, the second stack 163 may not be disconnected between the first pixel P1 and the second pixel P2, and between the second pixel P2 and the third pixel P3 arranged adjacent to each other with the trench T therebetween on the charge generation layer 162. Accordingly, charges may move through the second stack 163 between the first pixel P1 and the second pixel P2 and between the second pixel P2 and the third pixel P3, which are arranged adjacent to each other with the trench T therebetween.

In this embodiment, the thickness of the second stack 163 corresponding to the trench T region where the charge generation layer 162 is disconnected may be less than the thickness of the second stack 163 corresponding to the region where the charge generation layer 162 is disposed.

Due to the structure of the first stack 161, the charge generation layer 162, the recess portions R, and the second stack 163, an air gap AG may be formed inside the light emitting layer 16. The air gap AG may be provided inside the trench T to extend up to the top of the trench T. In addition, in an embodiment the width of the air gap AG may decrease from the lower part towards the upper part of the air gap AG. However, embodiments of the present inventive concept are not necessarily limited thereto.

According to an embodiment, the air gap AG may be formed in a ‘t’ shape, for example, by the recess portion R formed by a portion of the second separator 152 being concavely inserted into the substrate 11 in a horizontal direction. By the air gap AG containing one or more recess portions R, the charge generation layer 162 may be disconnected inside the trench T, including in a region overlapping the recess portion R. By configuring the charge generation layer 162 to be disconnected inside the trench T, the movement of charges between adjacent pixels of the plurality of pixels P1 to P3 may be reduced or eliminated to prevent occurrence of leakage current.

The second electrode 17 may be formed on the second stack 163 (e.g., formed directly thereon). The second electrode 17 may function as a cathode of the light emitting display apparatus 1. In an embodiment, the second stack 163 may be formed without being disconnected. Therefore, the second electrode 17 may be stably deposited on the light emitting layer 16, and a portion overlapping a region of the trench T may have a concave shape.

In an embodiment, the light emitting display apparatus 1 may be formed by an upper light emitting method. In an embodiment, the second electrode 17 may include a transparent metal material such as indium tin oxide (ITO) or indium zinc oxide (IZO) to transmit light emitted from the light emitting layer 16 upward. In addition, the second electrode 17 may be formed of a single layer or multiple layers.

The encapsulation layer 18 may be formed on the second electrode 17 (e.g., formed directly thereon). The encapsulation layer 18 may be formed to cover the second electrode 17. The encapsulation layer 18 may serve to prevent oxygen or moisture from penetrating into the light emitting layer 16 and the second electrode 17. In an embodiment, the encapsulation layer 18 may be made of an inorganic material, an organic material, or a mixture of an inorganic material and an organic material, and may be formed as a single layer or multiple layers.

According to a comparative example, in the light emitting display apparatus including the trench, when the depth of the trench H (see FIG. 3) increases, the charge generation layer is disconnected, but the second electrode is also disconnected. Alternatively, when the depth of the trench is less, the second electrode is connected, but a problem in which the charge generation layer is also connected is caused.

The light emitting display apparatus 1 of an embodiment of the present inventive concept may easily disconnect the charge generation layer 162 by forming, in the separator 15, a recess portion R formed by being concavely inserted into the substrate 11 in a horizontal direction. In addition, since the charge generation layer 162 may be disconnected by forming the recess portion R, the second electrode 17 may be connected without being disconnected.

The light emitting display apparatus 1 according to the embodiments may have a structure in which the charge generation layer 162 is disconnected and the second electrode 17 is connected. Therefore, despite the disconnection of the charge generation layer 162 and the connection structure of the second electrode 17, the depth H and width W designs of the trench T may be variously arranged.

On the bottom surface of the encapsulation layer 18, a region overlapping the trench T may have a concave shape. For example, since the encapsulation layer 18 covers the top surface of the second electrode 17, the encapsulation layer 18 has a concave bottom surface in a region overlapping the trench T, and the encapsulation layer 18 may be formed to fill the concave region of the second electrode 17. The top surface of the encapsulation layer 18 may be formed to be flat.

The color filter 19 may be formed on the encapsulation layer 18 (e.g., formed directly thereon). In an embodiment, the color filter 19 may include a first color filter 191 of red (R) provided in the first pixel P1, a second color filter 192 of green (G) provided in the second pixel P2, and a third color filter 193 of blue (B) provided in the third pixel P3.

Therefore, in the first pixel P1, only red (R) light may be transmitted when the white (W) light emitted from the light emitting layer 16 passes through the first color filter 191 of red (R). In the second pixel P2, when the white (W) light emitted from the light emitting layer 16 passes through the second color filter 192 of the green G, only the green (G) light may be transmitted. In the third pixel P3, when the white (W) light emitted from the light emitting layer 16 passes through the third color filter 193 of the blue (B), only the blue (B) light may be transmitted. In an embodiment, a protective layer may be additionally provided on the color filter 19.

According to an embodiment of the present inventive concept, the charge generation layer 162 may be disconnected in the boundary region between the adjacent pixels of the plurality of pixels P1 to P3 through the separator 15 in which the recess portion R formed in the trench T is formed. Accordingly, generation of a side leakage current flowing in each of the boundary regions between the adjacent two pixels of the plurality of pixels P1 to P3 may be prevented. For example, the charge generation layer 162 may be a lower resistive material than the first stack 161 and the second stack 163. In an embodiment, since the n-type charge generation layer constituting the charge generation layer 162 may include a metal material, conductivity of the charge generation layer 162 may be greater than that of the first stack 161 and the second stack 163.

The movement of charges between the adjacent pixels of the plurality of pixels P1 to P3 is mainly achieved through the charge generation layer 162, and the movement of charges through the second stack 163 is insignificant. Therefore, by configuring the charge generation layer 162 to be disconnected inside the trench T, the movement of charges between adjacent pixels of the plurality of pixels P1 to P3 may be reduced or eliminated to prevent occurrence of leakage current. In addition, using the separator 15 where the recess portion R is formed, it is possible to easily form a structure in which the charge generation layer 162 is disconnected without disconnecting the second electrode 17. For example, the degree of freedom of design of the depth H and width W of the trench T for disconnection of the charge generation layer 162 may increase.

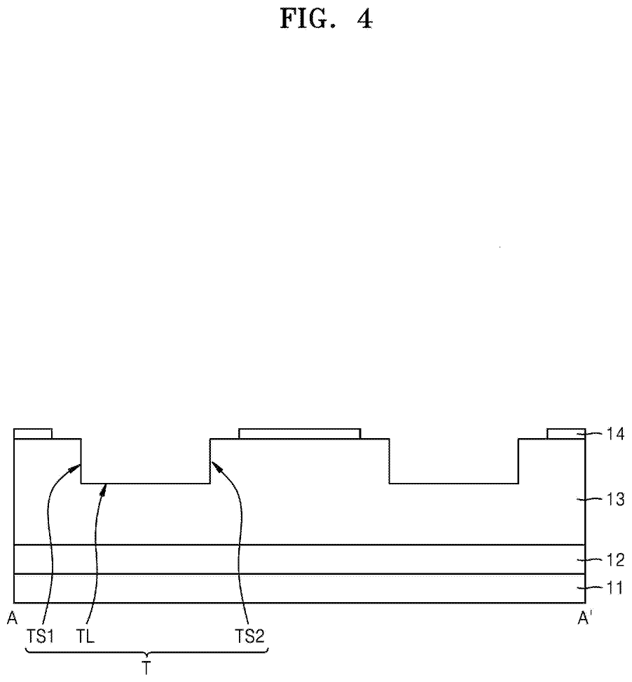

FIGS. 4 to 7 are cross-sectional views sequentially illustrating a process of manufacturing the light emitting display apparatus according to an embodiment of FIG. 2.

Referring to FIG. 4, the circuit element layer 12 may be formed on the substrate 11 (e.g., formed directly thereon), and the insulating layer 13 may be formed on the circuit element layer 12 (e.g., formed directly thereon). The trench T may be formed on the insulating layer 13. The first electrode 14 may be formed on a portion of the insulating layer 13 that does not overlap the trench T (e.g., in the vertical direction). The trenches T may be formed in a boundary region between the first pixel P1 and the second pixel P2 and a boundary region between the second pixel P2 and the third pixel P3. In an embodiment, the trenches T may be formed by etching the insulating layer 13.

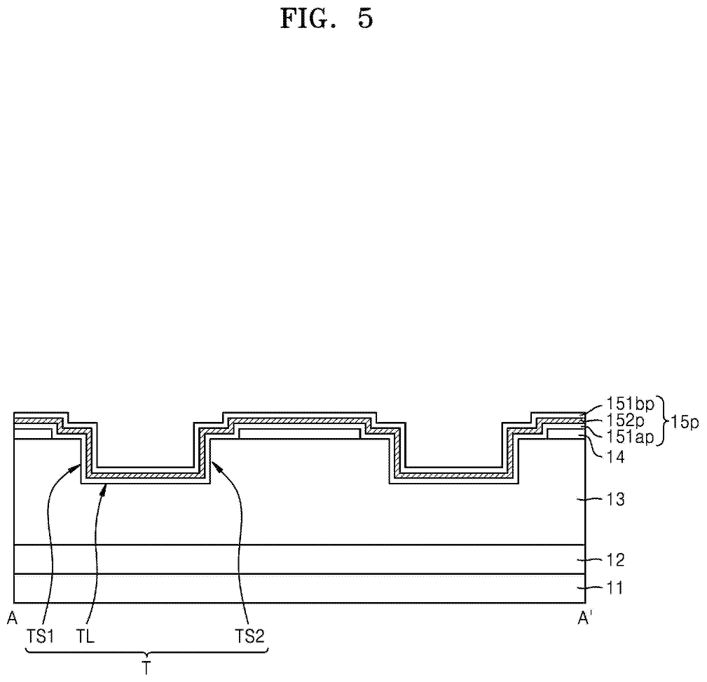

Referring to FIG. 5, a preliminary separator 15p may be formed on the insulating layer 13 and the first electrode 14. The preliminary separator 15p may include first preliminary separators 151ap and 151bp and a second preliminary separator 152p between the first preliminary separators 151ap, 151bp. For example, the first preliminary separators 151ap and 151bp and the second separator 152p may be stacked alternately. In an embodiment, the first preliminary separators 151ap and 151bp may include silicon nitride, and the second preliminary separator 152p may include silicon oxide. However, embodiments of the present inventive concept are not necessarily limited thereto, and the first preliminary separators 151ap and 151bp and the second preliminary separator 152p may include materials having different etching selectivity from each other.

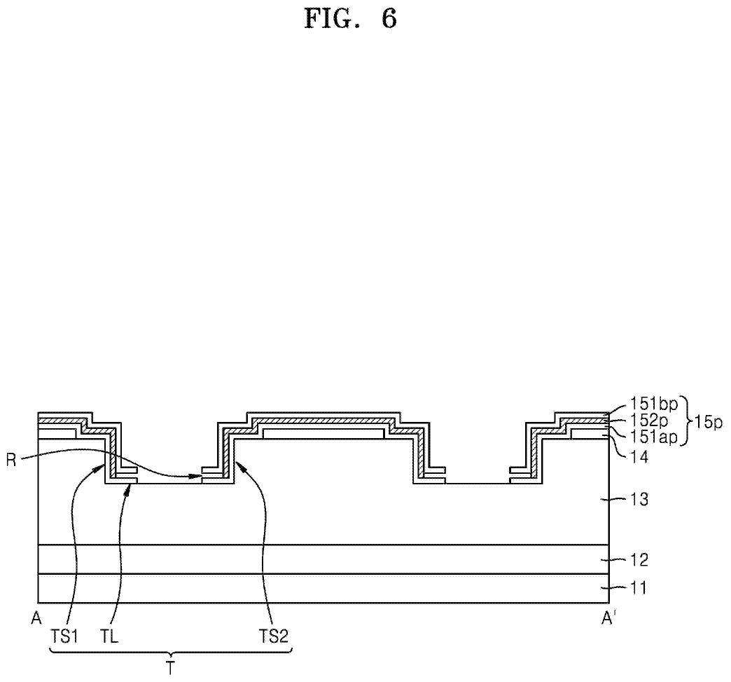

Referring to FIG. 6, a portion of the preliminary separator 15p may be etched. For example, a portion of the preliminary separator 15p formed on the bottom surface TL of the trench T may be etched. In an embodiment, a photoresist may be formed on the preliminary separator 15p, and a portion of the preliminary separator 15p may be etched.

In addition, a portion of the preliminary separator 15p may be removed to form the recess portion R. For example, each of the recess portions R may be concavely formed by being inserted into (e.g., defined in) a portion of the second preliminary separator 152p in a horizontal direction parallel to the substrate 11. For example, in an embodiment an entirety of the second preliminary separator 152p that extends in a horizontal direction overlapping the trench T may be removed to form the recess portion R. However, embodiments of the present inventive concept are not necessarily limited thereto. In an embodiment, a portion of the second preliminary separator 152p may be etched using an etching selectivity of silicon oxide and silicon nitride, and a recess portion R may be formed.

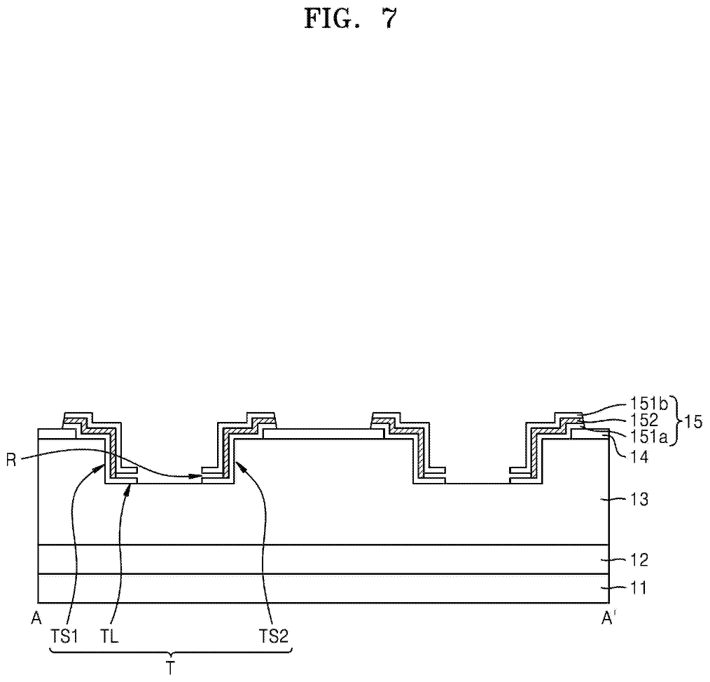

Referring to FIG. 7, a portion of the preliminary separator 15p may be etched to form a separator 15. As the preliminary separator 15p is etched, a portion of the top surface of the first electrode 14 may be exposed. In an embodiment, the separator 15, such as one end of the separator 15, may be formed to cover both ends (e.g., lateral ends) of the first electrode 14. Accordingly, the exposed region of the first electrode 14 exposed without being covered by the separators 15 may be a light emitting region.

The separators 15 may include recess portions R defined in a portion of the second separator 152 concavely in a horizontal direction. The separators 15 may be formed to cover the first and second sidewalls TS1 and TS2 of the trenches T. In addition, the separators 15 may cover at least a portion of the bottom surfaces TL of the trenches T.

Referring back to FIG. 2, the light emitting layer 16 may be formed above the insulating layer 13, the separator 15, and the first electrode 14. As described above, the emission layer 16 may include the first stack 161, the charge generation layer 162, and the second stack 163. The first stack 161, the charge generation layer 162, and the second stack 163 may be sequentially stacked (e.g., in a vertical direction). Due to the structure of the first stack 161, the charge generation layer 162, the recess portions R, and the second stack 163, the air gap AG may be formed inside the light emitting layer 16.

The light emitting layer 16 may be formed inside and above the trench T. In an embodiment in which the light emitting layer 16 is formed inside the trench T, at least a portion of the light emitting layer 16 may be disconnected by the recess portion R. Since the embodiment includes the recess portion R, disconnection of the light emitting layer 16 may be structurally easy. For example, the first stack 161 and the charge generation layer 162 may be disconnected by the recess portion R.

The second electrode 17 may be formed on the second stack 163 (e.g., formed directly thereon). The second stack 163 may be formed without being disconnected. The encapsulation layer 18 may be formed on the second electrode 17 (e.g., formed directly thereon). The color filter 19 including the first color filter 191, the second color filter 192, and the third color filter 193 may be formed on the encapsulation layer 18 (e.g., formed directly thereon).

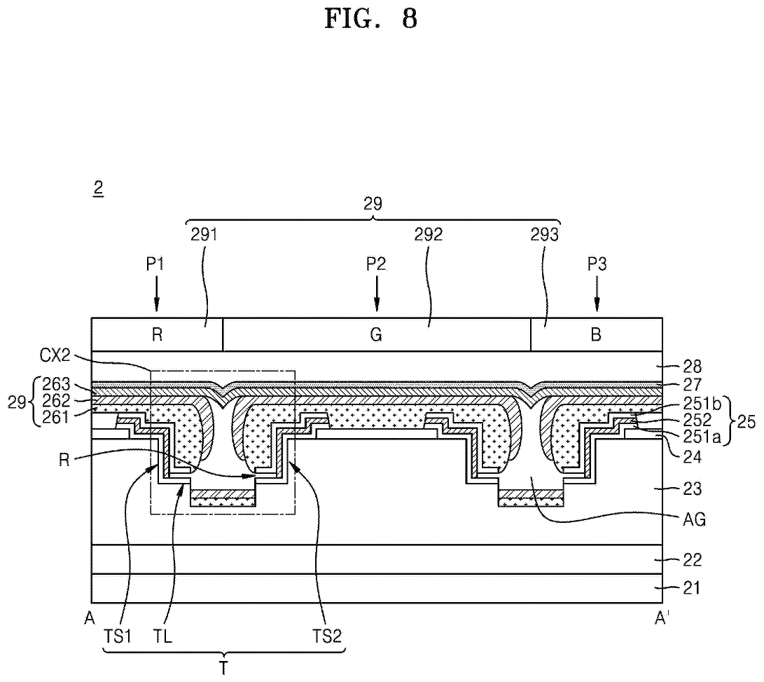

FIG. 8 is a cross-sectional view schematically illustrating a cross-section taken along line AA′ of the light emitting display apparatus of FIG. 1 according to an embodiment.

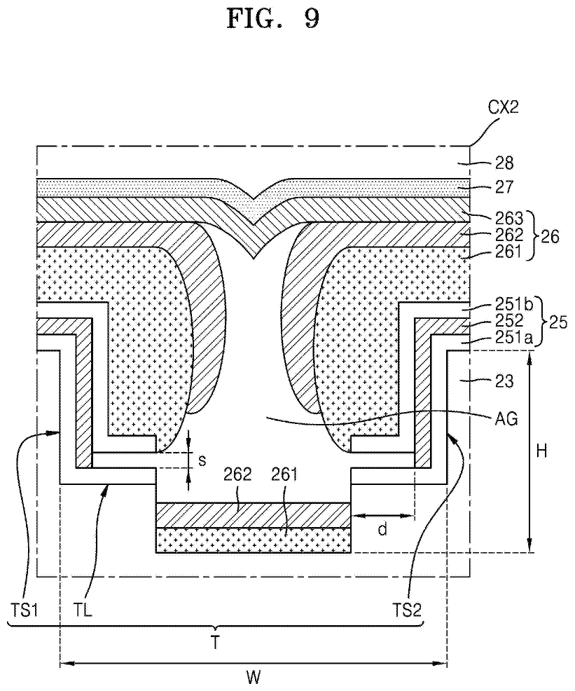

FIG. 9 is an enlarged cross-sectional view of a portion CX2 of FIG. 8.

In the light emitting display apparatus 2 of FIGS. 8 and 9 according to an embodiment, the description of the configuration and characteristics identical to or corresponding to the light emitting display apparatus 1 according to embodiments of FIGS. 2 to 7 is replaced by the description of FIGS. 2 to 7 and a repeated description may be omitted for economy of description.

Referring to FIGS. 8 and 9, the light emitting display apparatus 2 according to an embodiment may include all or a portion of a substrate 21, a circuit element layer 22, an insulating layer 23, a first electrode 24, a separator 25, a light emitting layer 26, a second electrode 27, an encapsulation layer 28, and a color filter 29.

According to an embodiment, a portion of the bottom surface TL of the trench T may be arranged at a lower level than the bottom surface of the separator 25. In an embodiment, a portion of the bottom surface TL of the trench T may have a concave shape. For example, a portion of the bottom surface TL of the trench T, which does not overlap the separator 25 may be recessed. As a portion of the bottom surface TL of the trench T is recessed, the depth H of the trench T may be increased as compared to an embodiment shown in FIG. 2.

The first stack 261 and the charge generation layer 262 may be sequentially formed on the bottom surface of the trench T (e.g., in a vertical direction). However, the first stack 261 and the charge generation layer 262 may be disconnected by the recess portion R in the inside of the trench T including in a region overlapping the recess portion R.

For example, the first stack 261 formed on the first sidewall TS1 of the trench T, the first stack 261 formed on the second sidewall TS2 of the trench T, and the first stack 261 formed on the bottom surface TL of the trench T may not be connected with one another. Accordingly, charges may not move through the first stack 161 between the first pixel P1 and the second pixel P2 and between the second pixel P2 and the third pixel P3, which are arranged adjacent to each other with the trench T therebetween.

In addition, the charge generation layer 262 formed on the first sidewall TS1 of the trench T, the charge generation layer 262 formed on the second sidewall TS2 of the trench T, and the charge generation layer 262 formed on the bottom surface TL of the trench T may not be connected with one another. Accordingly, charges may not move through the charge generation layer 262 between the first pixel P1 and the second pixel P2 and between the second pixel P2 and the third pixel P3, which are arranged adjacent to each other with the trench T therebetween.

By configuring the charge generation layer 262 to be disconnected inside the trench T, the movement of charges between adjacent pixels of the plurality of pixels P1 to P3 may be reduced or eliminated to prevent occurrence of leakage current.

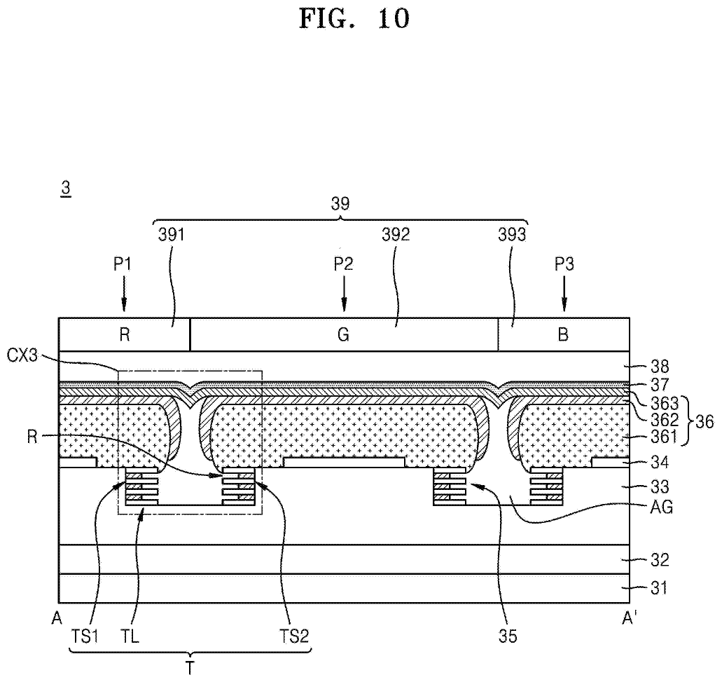

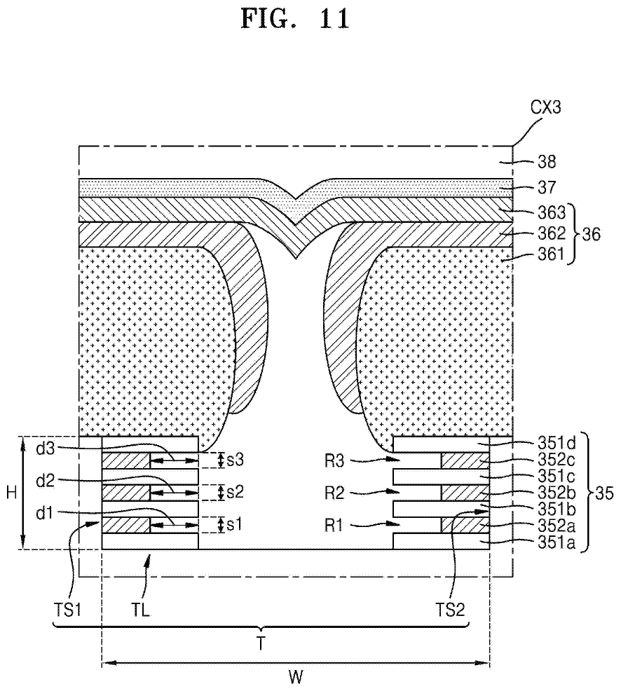

FIG. 10 is a cross-sectional view schematically illustrating a cross-section taken along line AA′ of the light emitting display apparatus of FIG. 1 according to another embodiment. FIG. 11 is an enlarged cross-sectional view of a portion CX3 of FIG. 10.

In the light emitting display apparatus 3 of FIGS. 10 and 11 according to an embodiment, the description of the configuration and characteristics identical to or corresponding to the light emitting display apparatus 1 according to embodiments of FIGS. 2 to 7 is replaced by the description of FIGS. 2 to 7 and a repeated description may be omitted for economy of description.

Referring to FIGS. 10 and 11, the light emitting display apparatus 3 according to another embodiment may include all or part of a substrate 31, a circuit element layer 32, an insulating layer 33, a first electrode 34, a separator 35, a light emitting layer 36, a second electrode 37, an encapsulation layer 38, and a color filter 39.

In the light emitting display apparatus 3 according to an embodiment, the separators 35 may be formed on the first and second sidewalls TS1 and TS2 of the trench. In an embodiment, the separators 35 may include a plurality of first separators 351a, 351b, 351c, and 351d and a plurality of second separators 352a, 352b, and 352c. For example, the separator 35 may be formed by alternately stacking four first separators 351a, 351b, 351c, and 351d and three second separators 352a, 352b, and 352c one after another. However, embodiments of the present inventive concept are not necessarily limited thereto and the number of the plurality of first and second separators may vary. In an embodiment, the first separators 351a, 351b, 351c, and 351d may include silicon nitride, and the second separators 352a, 352b, and 352c may include silicon oxide.

In addition, the separator 35 may include a plurality of recess portions R1 to R3. Each of the plurality of recess portions R1 to R3 may be concavely formed by being inserted into (e.g., defined in) a portion of each of the second separators 352a, 352b, and 352c in a horizontal direction parallel to the substrate 31.

For example, the separator 35 may include a first recess portion R1 adjacent to a bottom surface of the trench, a second recess portion R2 formed to be spaced apart from the first recess portion R1 in a direction perpendicular to the substrate 31 (e.g., in a vertical direction), and a third recess portion R3 formed to be spaced apart from the second recess portion R2 in a direction perpendicular to the substrate 31 (e.g., in a vertical direction).

In FIG. 10, it is illustrated that three recess portions R1 to R3 are formed in a vertical direction inside one trench T. However, embodiments of the present inventive concept are not necessarily limited thereto. In addition, the first to third recess portions R1 to R3 may be formed at equal intervals from each other. However, embodiments of the present inventive concept are not necessarily limited thereto.

The separator 35 including the first to third recess portions R1 to R3 may be formed on the first sidewall TS1. The separator 35 including the first to third recess portions R1 to R3 may be formed on the second sidewall TS2. However, embodiments of the present inventive concept are not necessarily limited thereto, and a separator 35 including the first to third recess portions R1 to R3 may be formed only on the first sidewall TS1 or the second sidewall TS2. In addition, the separator 35 formed on the first sidewall TS1 and the separator 35 formed on the second sidewall TS2 may include a different number of recess portions from each other.

In some embodiments, depths and heights of the plurality of recess portions R1 to R3 may be different from each other. The depth d1 of the first recess portion R1, the depth d2 of the second recess portion R2, and the depth d3 of the third recess portion R3 may be different from one another. In some embodiments, the height s1 of the first recess portion R1, the height s2 of the second recess portion R2, and the height s3 of the third recess portion R3 may be different from one another. For example, in an embodiment the depth d1 of the first recess portion R1 may be about 34 nm, and the depth d2 of the second recess portion R2 may be about 43 nm. In addition, the height s1 of the first recess portion R1 may be about 100 nm, and the height s2 of the second recess portion R2 may be about 50 nm. However, embodiments of the present inventive concept are not necessarily limited thereto, and the depths and heights of the plurality of recess portions R1 to R3 may be the same as each other in some embodiments.

The first stack 361 and the charge generation layer 362 may be disconnected by the plurality of recess portions R1 to R3 inside the trench T, including in a region overlapping with the plurality of recess portions R1 to R3. For example, the first stack 361 and the charge generation layer 362 may be disconnected between the third recess portion R3 at the top of the plurality of recess portions R1 to R3 and the first recess R1 at the bottom thereof.

For example, the first stack 361 formed on the first sidewall TS1 of the trench T and the first stack 361 formed on the second sidewall TS2 of the trench T may not be connected with each other. In addition, the charge generation layer 362 formed on the first sidewall TS1 of the trench T and the charge generation layer 362 formed on the second sidewall TS2 of the trench T may not be connected with each other. Accordingly, charges may not move through the charge generation layer 362 between the first pixel P1 and the second pixel P2 and between the second pixel P2 and the third pixel P3, which are arranged adjacent to each other with the trench T therebetween.

By configuring the charge generation layer 362 to be disconnected inside the trench T, the movement of charges between adjacent pixels of the plurality of pixels P1 to P3 may be reduced or eliminated to prevent occurrence of leakage current.

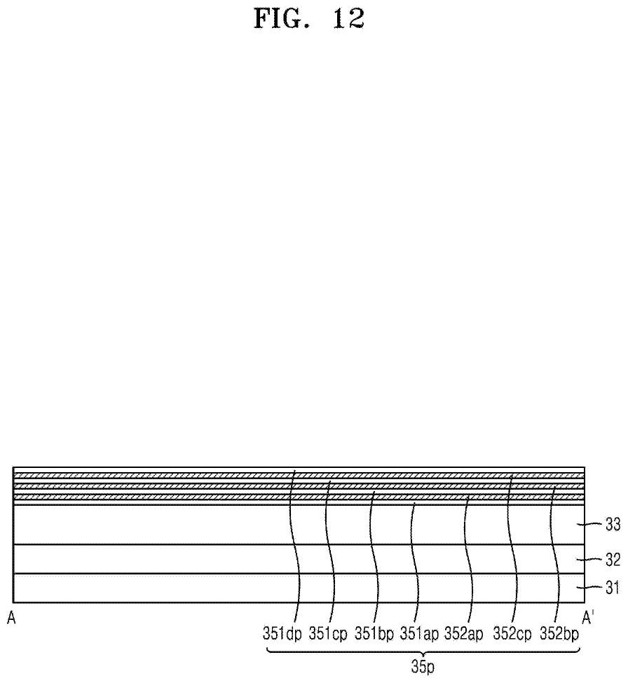

FIGS. 12 to 15 are cross-sectional views sequentially illustrating a process of manufacturing the light emitting display apparatus according to an embodiment of FIG. 10.

Referring to FIG. 12, the circuit element layer 32 may be formed on the substrate 31, and the insulating layer 33 may be formed on the circuit element layer 32. A preliminary separator 35p may be formed on the insulating layer 33. The preliminary separator 35p may include a plurality of first preliminary separators 351ap, 351bp, 351cp, and 351dp and a plurality of second preliminary separators 352ap, 352bp, and 352cp. For example, in an embodiment the preliminary separator 35p may be formed by alternately stacking four first preliminary separators 351ap, 351bp, 351cp, and 351dp and three second preliminary separators 352ap, 352bp, and 352cp one after another (e.g., in a vertical direction). In this embodiment, the first preliminary separators 351ap, 351bp, 351cp, and 351dp may include silicon nitride, and the second preliminary separators 352ap, 352bp, and 352cp may include silicon oxide. However, embodiments of the present inventive concept are not necessarily limited thereto, and the first preliminary separators 351ap, 351bp, 351cp, and 351dp and the second preliminary separators 352ap, 352bp, and 352cp may include materials having different etching selectivity.

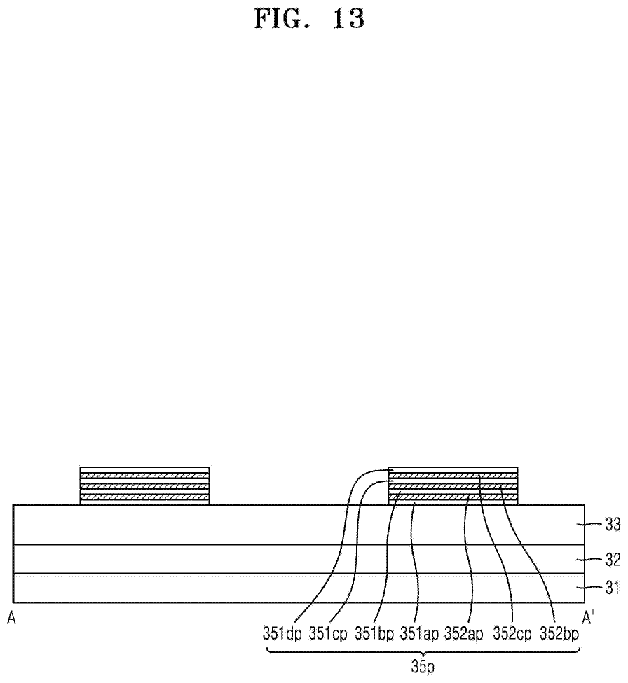

Referring to FIG. 13, a portion of the preliminary separator 35p may be etched. For example, a portion of the preliminary separator 35p may be etched except for portions corresponding to the boundary region between the first pixel P1 and the second pixel P2 of FIG. 10 and the boundary region between the second pixel P2 and the third pixel P3.

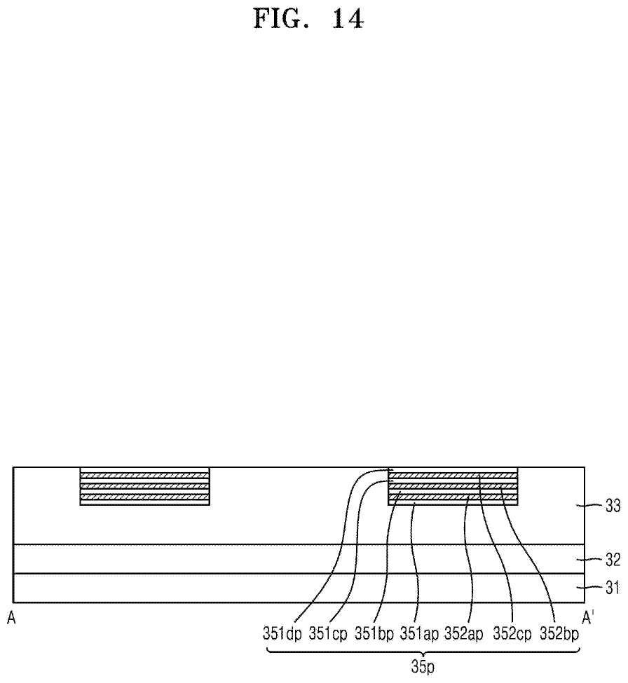

Referring to FIG. 14, the insulating layer 33 may be deposited and a chemical mechanical polishing (CMP) process may be performed. The top surfaces of the insulating layer 33 and the preliminary separator 35p may be positioned at the same level by the CMP process.

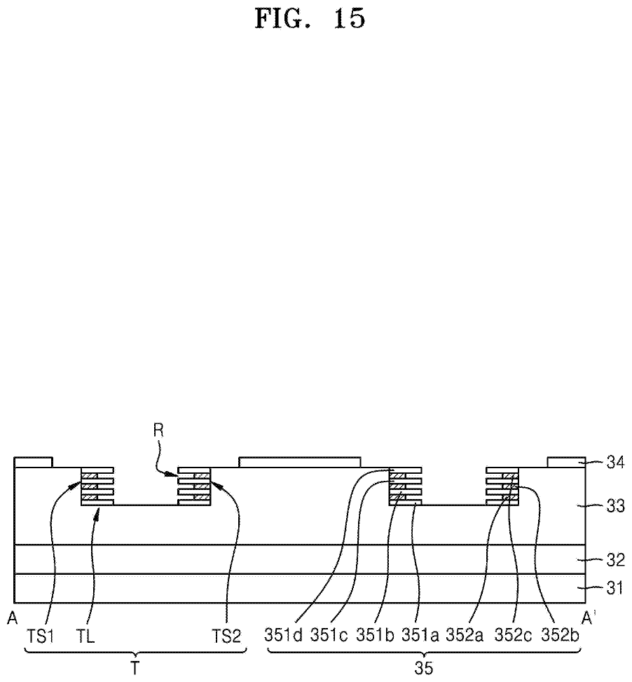

Referring to FIG. 15, a portion of the preliminary separator 35p may be etched to form a separator 35. For example, in an embodiment a photoresist may be formed on the preliminary separator 35p, and a portion of the preliminary separator 35p may be etched. In addition, the first electrode 34 may be formed on the insulating layer 33.

A portion of the preliminary separator 15p may be removed to form the plurality of recess portions R1 to R3. For example, each of the plurality of recess portions R1 to R3 may be concavely formed by being inserted into (defined in) a portion of each of the second preliminary separators 352ap, 352bp, and 352cp in a horizontal direction parallel to the substrate 31. In an embodiment a portion of each of the second preliminary separators 352ap, 352bp, and 352cp may be etched using an etching selectivity of the silicon oxide and the silicon nitride, to form the plurality of recess portions R1 to R3.

Referring back to FIG. 10, the light emitting layer 36 may be formed above the insulating layer 33, the separator 35, and the first electrode 34. As described above, the emission layer 36 may include the first stack 361, the charge generation layer 362, and the second stack 363. The first stack 361, the charge generation layer 362, and the second stack 363 may be sequentially stacked (e.g., in a vertical direction). Due to the structure of the first stack 361, the charge generation layer 362, the plurality of recess portions R, and the second stack 363, the air gap AG may be formed inside the light emitting layer 36.

The light emitting layer 36 may be formed inside and above the trench T. In an embodiment in which the light emitting layer 36 is formed inside the trench T, at least a portion of the light emitting layer 36 may be disconnected by the plurality of recess portions R1 to R3. Since an embodiment shown in FIG. 10 includes the plurality of recess portions R1 to R3, disconnection of the light emitting layer 36 may be structurally easy. For example, the first stack 361 and the charge generation layer 362 may be disconnected by the plurality of recess portions R1 to R3.

The second electrode 37 may be formed on the second stack 363 (e.g., formed directly thereon). The second stack 363 may be formed without being disconnected. The encapsulation layer 38 may be formed on the second electrode 37. The color filter 39 including the first color filter 391, the second color filter 392, and the third color filter 393 may be formed on the encapsulation layer 38 (e.g., formed directly thereon).

While the present inventive concept has been particularly shown and described with reference to non-limiting embodiments thereof, it will be understood that various changes in form and details may be made therein without departing from the spirit and scope of the present inventive concept.

What is claimed is:

1. A light emitting display apparatus comprising:
an insulating layer arranged on a substrate, the insulating layer including a trench;
a first electrode arranged on the insulating layer;
a light emitting layer arranged on the insulating layer and the first electrode;
a separator arranged between the insulating layer and the light emitting layer, the separator covering at least one sidewall of the trench; and
a second electrode arranged on the light emitting layer,
wherein the separator includes a recess portion having at least a portion concavely defined in a horizontal direction on the substrate.

2. The light emitting display apparatus of claim 1, wherein the separator comprises a first separator and a second separator that are alternately stacked on one another.

3. The light emitting display apparatus of claim 2, wherein:
the first separator comprises silicon nitride; and
the second separator comprises silicon oxide.

4. The light emitting display apparatus of claim 2, wherein the recess portion is defined concavely in a horizontal direction on the substrate in at least a portion of the second separator.

5. The light emitting display apparatus of claim 1, wherein the recess portion is positioned at a same level on a first sidewall and a second sidewall of the trench.

6. The light emitting display apparatus of claim 1, wherein at least a portion of a lower surface of the trench is arranged at a lower level than a lower surface of the separator.

7. The light emitting display apparatus of claim 6, wherein a portion of the light emitting layer is arranged on a lower surface of the trench.

8. The light emitting display apparatus of claim 1, wherein the recess portion comprises:
a first recess portion adjacent to a bottom surface of the trench; and
a second recess portion spaced apart from the first recess portion in a vertical direction perpendicular to the substrate.

9. The light emitting display apparatus of claim 8, wherein the first recess portion and the second recess portion are spaced apart at equal intervals in the vertical direction perpendicular to the substrate.

10. The light emitting display apparatus of claim 8, wherein:
a depth of the first recess portion is different from a depth of the second recess portion; and
a height of the first recess portion is different from a height of the second recess portion.

11. The light emitting display apparatus of claim 1, wherein the separator comprises one end covering at least a portion of the first electrode.

12. The light emitting display apparatus of claim 1, wherein the light emitting layer comprises a charge generation layer, wherein the charge generation layer is disconnected inside the trench, including in a region overlapping the recess portion.

13. A light emitting display apparatus comprising:
an insulating layer arranged on a substrate, the insulating layer including a trench,
a first electrode arranged on the insulating layer,
a light emitting layer arranged on the insulating layer and the first electrode,
a separator arranged between the insulating layer and the light emitting layer, the separator covering at least one sidewall of the trench, and
a second electrode arranged on the light emitting layer, wherein
the separator includes a recess portion having at least a portion that is concavely defined in a horizontal direction on the substrate, and
the light emitting layer includes a charge generation layer that is disconnected inside the trench, including in a region overlapping the recess portion.

14. The light emitting display apparatus of claim 13, wherein:
the recess portion comprises a plurality of recess portions arranged along the sidewall of the trench in a vertical direction perpendicular to the substrate; and
the charge generation layer is disconnected between a first recess portion arranged at an uppermost end of the recess portions and a second recess portion arranged at a lowermost end of the recess portions.

15. The light emitting display apparatus of claim 13, wherein a disconnected portion of the charge generation layer is arranged on a lower surface of the trench.

16. The light emitting display apparatus of claim 13, wherein the separator comprises:
a first separator including silicon nitride; and
a second separator alternately stacked with the first separator, the second separator including silicon oxide.

17. The light emitting display apparatus of claim 16, wherein the recess portion is defined concavely in a horizontal direction on the substrate in at least a portion of the second separator.

18. A light emitting display apparatus comprising:
a substrate having a plurality of pixels, the plurality of pixels including first to third pixels;
an insulating layer arranged on the substrate, the insulating layer including a trench;
a first electrode arranged on the insulating layer;
a light emitting layer arranged on the insulating layer and the first electrode;
a separator arranged between the insulating layer and the light emitting layer, the separator covering at least one sidewall of the trench;
a second electrode arranged on the light emitting layer; and
an encapsulation layer arranged on the second electrode,
wherein the separator includes at least one first separator and at least one second separator that are formed alternately stacked on one another,
the second separator includes a recess portion having at least a portion concavely defined in a horizontal direction on the substrate, and
the light emitting layer includes a charge generation layer that is disconnected inside the trench, including in a region overlapping the recess portion.

19. The light emitting display apparatus of claim 18, wherein:
the first separator comprises silicon nitride; and
the second separator comprises silicon oxide.

20. The light emitting display apparatus of claim 18, wherein the recess portion comprises:
a first recess portion adjacent to a bottom surface of the trench; and
a second recess portion spaced apart from the first recess portion in a vertical direction perpendicular to the substrate.
